(19) United States
(12) Patent Application Publication
(10) Pub. No.: US 2020/0356004 A1
(43) Pub. Date: Nov. 12, 2020

(54) PHOTO-RESIST FOR SUPER-RESOLUTION OPTICAL LITHOGRAPHY

(71) Applicant: BOISE STATE UNIVERSITY, Boise, ID (US)

(72) Inventor: Bernard Yurke, Boise, ID (US)

(21) Appl. No.: 16/869,688

(22) Filed: May 8, 2020

Related U.S. Application Data
(60) Provisional application No. 62/844,989, filed on May 8, 2019.

(51) Int. Cl. G03F 7/038; G03F 7/039; G03F 7/16; G03F 7/20

(52) U.S. Cl. CPC G03F 7/038; G03F 7/039; G03F 7/70191; G03F 7/2037; G03F 7/16

(57) ABSTRACT

A photo-lithography system may include a first light source configured to generate a first light beam having a first wavelength. The first light beam may be modified, where an intensity of the first wavelength absent within a threshold radius from the center of the modified first light beam, and wherein the intensity of the first wavelength present a radius that is greater than the threshold radius. The system may include a second light source configured to generate a second light beam having a second wavelength that is present within the threshold radius from the center of the second light beam. A lens may focus the first light beam and the second light beam onto a layer of photoresist applied to a surface. The photoresist may include double-stranded deoxyribonucleic acid (DNA) oligomers and photochromic moieties intercalated therein.

### CROSS-REFERENCE TO RELATED APPLICATIONS

This application claims priority to U.S. Provisional Patent Application No. 62/844,989, filed on May 8, 2019, and entitled “Photo-Resist for Super-Resolution Optical Lithography and Ultrahigh Density Data Storage,” the contents of which are hereby incorporated by reference herein in their entirety.

### FIELD OF THE DISCLOSURE

This disclosure is generally related to the field of super-resolution optical systems and, in particular, to super-resolution optical lithography.

### BACKGROUND

Photolithography may be used in microfabrication applications to enable the deposition of material onto a substrate in a specified pattern. Typically, a photoresist material is applied to the substrate. Light may then be passed through a photomask and applied to the substrate to activate portions of the photoresist in a predetermined pattern. The activated portions of the photoresist may be chemically treated, which results in the activated portions being degraded and removed or in the inactive portions of the photoresist being degraded and removed. Whether the activated portions or the inactive portions are removed depends on the type of photoresist used and the chemical treatment.

Because current photolithography methods are based on the passage of light through a photomask, they may be limited by the nature of the light being used. For example, the intensity of a typical light beam, such as a collimated light beam from a laser, may have a gaussian distribution. A minimum width of the distribution may depend on a wavelength of the light. Thus, the resolution of typical photolithography processes may be limited based on the wavelength of the light. Other disadvantages may exist.

### SUMMARY

Disclosed herein is a photolithography system and method, and an associated photoresist material, that may overcome at least one of the disadvantages of typical photolithography systems and methods. The system may rely on producing a first light beam, e.g., a suppress beam, having a donut shaped intensity profile with a zero-intensity value in the middle. The first light beam may have a wavelength that suppresses activation of a photoresist. A second light beam, e.g., a write beam, having a gaussian-shaped intensity profile, may be combined with the first light beam. The second light beam may have a wavelength that activates the photoresist when alone, but that does not active the photoresist when in combination with the first light beam. Thus, only portions of the photoresist within the center of the donut-shaped intensity profile of the first light beam may be activated. This may enable better resolution as compared to typical photolithography systems.

In an embodiment, a photoresist material may include double-stranded deoxyribonucleic acid (DNA) oligomers. The material may further include photochromic moieties intercalated into the double-stranded DNA oligomers. A supramolecular interaction may exist between the double-stranded DNA oligomers and the photochromic moieties when the photochromic moieties have a first conformation and the supramolecular interaction may not exist between the double-stranded DNA oligomers and the photochromic moieties when the photochromic moieties have a second conformation.

In some embodiments, the photochromic moieties, when in the presence of light, may adopt the first conformation when a first wavelength of the light is greater than a first intensity threshold and a second wavelength of the light is greater than a second intensity threshold and the photochromic moieties may adopt the second conformation when the first wavelength of the light is less than the first intensity threshold and the second wavelength of light is greater than the second intensity threshold. In some embodiments, the photochromic moieties are part of a biszaobenzene based compound. In some embodiments, the double-stranded DNA oligomers dissociate in the absence of the supramolecular interaction. In some embodiments, the photo resist material may include a bonding agent configured to adhere the double-stranded DNA oligomers to the surface of a substrate.

In an embodiment, a photo-lithography method includes applying a layer of photoresist to a surface of a substrate, where the photoresist, when in the presence of light, is configured to remain inactive when a first wavelength of the light is greater than a first intensity threshold and a second wavelength of the light is greater than a second intensity threshold, and where the photoresist is configured to activate when the first wavelength of the light is less than the first intensity threshold and the second wavelength of light is greater than the second intensity threshold. The method further includes forming a light beam that has the first wavelength and the second wavelength, where an intensity of the first wavelength is less than the first intensity threshold and an intensity of the second wavelength is greater than the second intensity threshold within a threshold radius from the center of the light beam, and where the intensity of the first wavelength is greater than the first intensity threshold at a radius that is greater than the threshold radius. The method also includes directing the light beam onto the layer of photoresist.

In some embodiments, forming the light beam includes generating a first light beam having the first wavelength, where the first light beam has a first intensity profile that is below the first intensity threshold at a center of the first light beam and that increases as a function of distance from the center of the first light beam and that surpasses the first intensity threshold at the threshold radius from the center of the first light beam, generating a second light beam having the second wavelength, where the second light beam has a second intensity profile with a gaussian distribution that is greater than the second intensity threshold within the threshold radius from the center of the second light beam, and combining the first light beam and the second light beam.

In some embodiments, generating the first light beam includes passing the first light beam through a phase mask to form the first intensity profile. In some embodiments, the threshold radius is less than 1 nm. In some embodiments, the second wavelength is shorter than the first wavelength. In some embodiments, the first wavelength is in the visible light range and wherein the second wavelength is in the ultraviolet range. In some embodiments, the photoresist includes double-stranded DNA oligomers and photochromic moieties intercalated into the double-stranded DNA oligomers, where a supramolecular interaction exists between the double-stranded DNA oligomers and the photochromic moieties when the photochromic moieties have a first conformation, and where the supramolecular interaction does not exist between the double-stranded DNA oligomers and the photochromic moieties when the photochromic moieties have a second conformation. In some embodiments, the photochromic moieties, when in the presence of the light, adopt the first conformation when the first wavelength of the light is greater than the first intensity threshold and the second wavelength of the light is greater than the second intensity threshold, and the photochromic moieties adopt the second conformation when the first wavelength of the light is less than the first intensity threshold and the second wavelength of light is greater than the second intensity threshold.

In an embodiment, a photo-lithography system includes a first light source configured to generate a first light beam having a first wavelength. The system further includes a phase mask configured to modify the first light beam, where an intensity of the first wavelength of the modified first light beam is less than a first intensity threshold within a threshold radius from the center of the modified first light beam, and where the intensity of the first wavelength is greater than the first intensity threshold at a radius that is greater than the threshold radius. The system also includers a second light source configured to generate a second light beam having a second wavelength, where an intensity of the second wavelength of the second light beam is greater than a second intensity threshold within the threshold radius from the center of the second light beam. The system includes a lens configured to focus the first light beam and the second light beam onto a layer of photoresist applied to a surface of a substrate.

In some embodiments, the photoresist, when in the presence of the first light beam and the second light beam, is configured to remain inactive when the first wavelength is greater than the first intensity threshold and the second wavelength is greater than the second intensity threshold, and wherein the photoresist is configured to activate when the first wavelength is less than the first intensity threshold and the second wavelength is greater than the second intensity threshold. In some embodiments, the photoresist includes double-stranded DNA oligomers and photochromic moieties intercalated into the double-stranded DNA oligomers, where a supramolecular interaction exists between the double-stranded DNA oligomers and the photochromic moieties when the photochromic moieties have a first conformation, and where the supramolecular interaction does not exist between the double-stranded DNA oligomers and the photochromic moieties when the photochromic moieties have a second conformation. In some embodiments, the system includes a beam combiner configured to combine the first light beam with the second light beam before the first light beam and the second light beam pass through the lens. In some embodiments, the beam combiner includes a dichroic mirror, a beam splitter, a polarization beam splitter, or a combination thereof. In some embodiments, the first light source includes a first laser and the second light source includes a second laser. In some embodiments, the threshold radius is less than 1 nm.

### BRIEF DESCRIPTION OF THE DRAWINGS

FIG. 1 is a block diagram depicting an embodiment of a photo-lithography system.

FIG. 2 is a profile view depicting an embodiment of a combined intensity distribution for a suppress light beam and a write light beam.

FIG. 3 is a plan view depicting an embodiment of a combined intensity distribution for a suppress light beam and a write light beam.

FIG. 4 depicts regions of an embodiment of a combined intensity distribution as applied to a photoresist layer.

FIG. 5 is a symbolic depiction of an embodiment conformations of a photochromic moiety for use with a DNA-based photoresist.

FIG. 6 depicts an example of a photoresist material.

FIGS. 7A-7D depicts a photoresist material in various states depending on different wavelength applications.

FIG. 8 is a flow chart depicting a photolithography method.

While the disclosure is susceptible to various modifications and alternative forms, specific embodiments have been shown by way of example in the drawings and will be described in detail herein. However, it should be understood that the disclosure is not intended to be limited to the particular forms disclosed. Rather, the intention is to cover all modifications, equivalents and alternatives falling within the scope of the disclosure.

### DETAILED DESCRIPTION

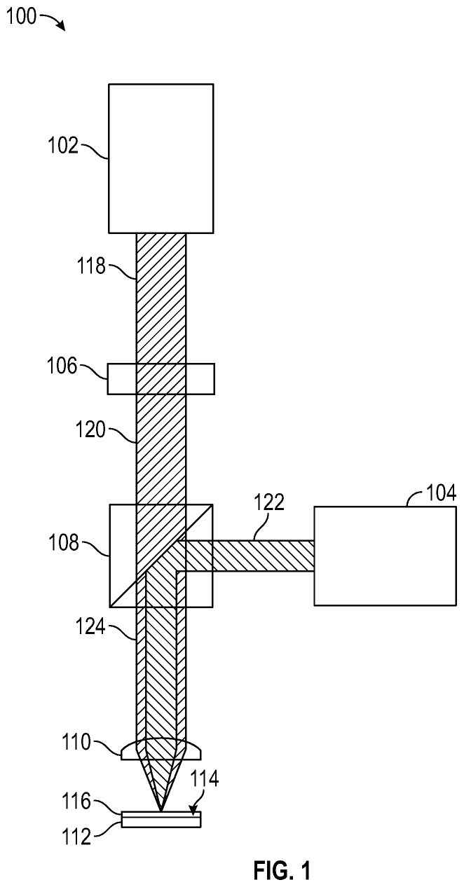

Referring to FIG. 1, an embodiment of a photo-lithography system 100 is depicted. The system 100 may include a first light source 102, a second light source 104, a phase mask 106, a beam combiner 108, and a lens 110. Although not depicted, in practice, the system 100 may include other optical systems such as stabilizing feedback electronics, optical shutters, a system to raster scan the light sources 102,104, and a stage holding a wafer or substrate that is being processed.

The first light source 102 may include a first laser or another type of light source configured to generate a first light beam 118 having a first wavelength. The second light source 104 may include a second laser or another type of light source configured to generate a second light beam 122 having a second wavelength. In some applications, the second wavelength may be shorter than the first wavelength. For example, first wavelength may be in the visible light range and the second wavelength may be in the ultraviolet range. Other wavelengths above, within, or below the visible range are also possible.

The phase mask 106 may be positioned within a path of the first light beam 118 and may be configured to perform beam shaping. For example, the phase mask 106 may be designed such that any collimated light beam having a gaussian intensity distribution and a predetermined wavelength may be modified to have a donut shaped distribution with a zero-intensity value at its center. Thus, light is considered to be absent at the center of the donut shaped distribution. As used herein, the “absence” of light means that the light falls below an intensity threshold. The intensity threshold may be based on an intensity level sufficient to activate or suppress a photoresist, as described herein. Similarly, the “presence” of light means that the light exceeds the intensity threshold. Different wavelengths of light may have different intensity thresholds depending on whether the light is used as a write beam or a suppress beam. The phase mask 106 may be used to generate a modified first light beam 120 that has a donut-shaped intensity distribution and that may be used as a suppress beam within the system 100 as described herein. Light may be absent at the center of the modified first light beam within a threshold radius of less than 1 nm. Although the system 100 depicts using the phase mask 106 for beam forming, other approaches may be used to form the modified first light beam 120.

The beam combiner 108 may be positioned within a path of both the modified first light beam 120 and the second light beam 122. A dichroic mirror, a beam splitter, a polarization beam splitter, or a combination thereof may be used as the beam combiner 108. The lens 110 may then be used to focus the combined light beam 124 onto a photoresist layer 116 positioned on a surface 114 of a substrate 112.

The photoresist layer 116 may include a photoresist that, when in the presence of the combined light beam 124, may be configured to remain inactive when both the first wavelength of the first light beam 118 and the second wavelength of the second light beam 122 are present. In other words, the first wavelength may suppress activation of the photoresist when the first wavelength of the first light beam 118 is greater than a first intensity threshold while the second wavelength of the second light beam 122 is also greater than a second intensity threshold. On the other hand, the photoresist may be configured to activate when the first wavelength is less than the first intensity threshold (e.g., the first wavelength is absent) and the second wavelength is greater than the second intensity threshold.

Because the first wavelength may be absent only from within a small threshold radius (e.g., less than 1 nm) of the center of the combined light beam 124, the system 100 may enable photolithography to be performed at much higher resolutions (e.g., 2 nm or less) than typical photolithography methods, which may be limited by the wavelength of the light. The higher resolution may improve the design of micro-circuitry and other microdevices. Other benefits may exist.

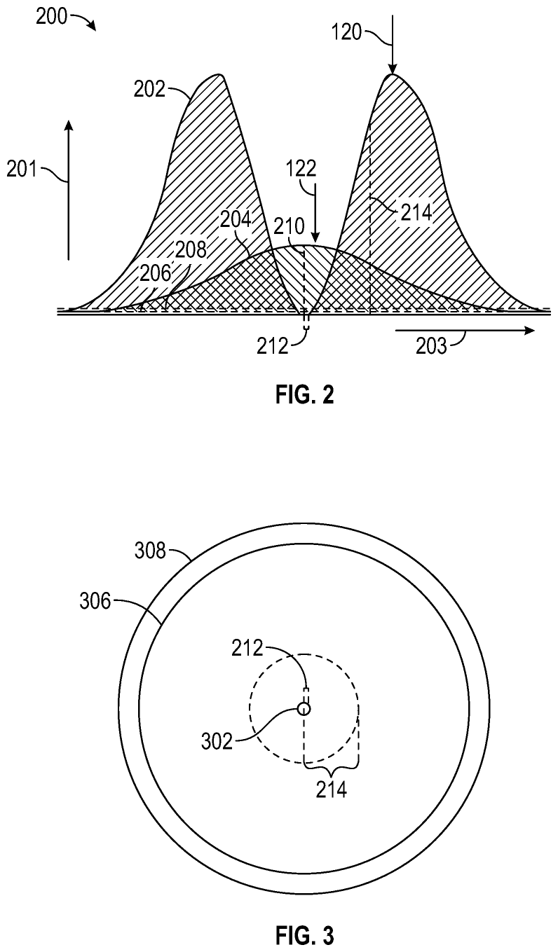

Referring to FIGS. 2 and 3, an embodiment of a combined intensity distribution 200 for a suppress light beam and a write light beam are depicted. FIG. 2 depicts a profile view of the combined intensity distribution 200. FIG. 3 depicts a plan view of the combined intensity distribution 200.

As shown in FIG. 2, the combined intensity distribution 200 may include a first intensity profile 202 associated with the modified first light beam 120 and a second intensity profile 204 associated with the second light beam 122. The intensity profiles 202, 204 are shown as a function of distance 203 from a center 210 of their respective light beams mapped to the intensity 201 of the light beam. The modified first light beam 120 (having the first intensity profile 202) may be a suppress light beam (having a first wavelength that suppresses activation of a photoresist) while the second light beam 122 (having the second intensity profile 204) may be a write light beam (having a second wavelength that activates the photoresist).

As shown in FIG. 2, at the center 210, the first intensity profile 202 may be zero and the second intensity profile 204 may peak. The first light beam may be considered to be absent from the center 210, while the second light beam is considered present. When applied to a photoresist, the photoresist may activate in response to a first wavelength associated with the modified first light beam 120 being absent while a second wavelength associated with the second light beam 122 is present.

As the distance 203 from the center 210 increases, the first intensity profile 202 may increase as well. A first intensity threshold 206 may be designated for determining whether the first light beam 120 is present or absent. The first intensity profile 202 of the first wavelength of the modified first light beam 120 may be less than the first intensity threshold 206 within a threshold radius 212 from the center 210 of the modified first light beam 120. The first intensity threshold 206 may be defined as the intensity level that is sufficient to suppress activation of a photoresist as described herein. A second intensity threshold 208 may be designated for determining whether the second light beam 122 is present. Because the shape of the second intensity profile 204 is gaussian, having a peak at the center 210, the intensity of the first wavelength may be greater than the second intensity threshold 208 at the threshold radius 212. Thus, within the threshold radius 212 (depicted as a first region 302 in FIG. 3), an intensity of the first wavelength of the modified first light beam 120 may be less than the first intensity threshold 206 within the threshold radius 212 from the center 210 and an intensity of the second wavelength of the second light beam 122 may be greater than the second intensity threshold 208.

Outside the threshold radius 212, for example at a radius 214, an intensity of the first wavelength of the modified first light beam 120 may be greater than the first intensity threshold 206. So long as the first wavelength of the modified first light beam 120 is greater than the first intensity threshold 206, the second light beam 122 may be prevented from activating the photoresist. Thus, a second region (depicted as the region 306 in FIG. 3) may exist where both the modified first light beam 120 and the second light beam 122 are considered to be present. In the region 306, the photoresist may not be activated. As shown in FIG. 2, the second intensity profile 204 eventually drops below the second intensity threshold 208. This results in a third region 308, where the modified first light beam 120 is present while the second light beam 122 is absent. As with the region 306, the photoresist is not activated in the region 308 because the second light beam 122, which is the write beam, is absent. The only region of FIG. 3 where the photoresist may be activated is the first region 302 within the threshold radius 212. As noted, the threshold radius may be less than 1 nm.

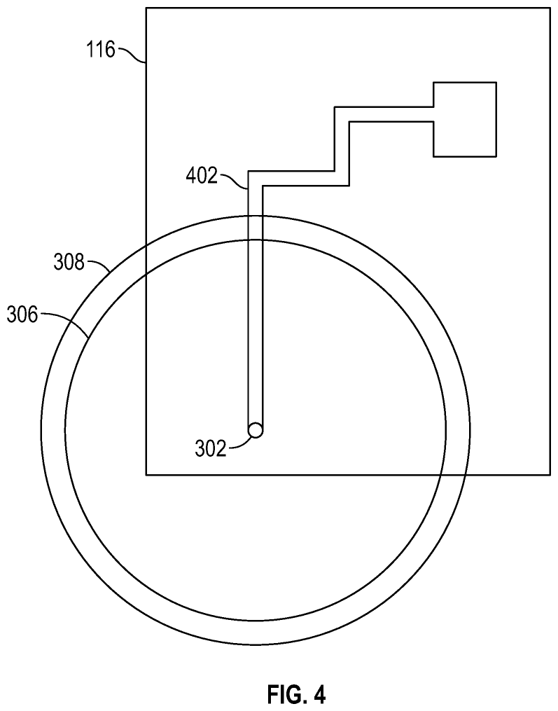

Referring to FIG. 4, the regions 302, 306, 308 of FIG. 3 are depicted as being applied to the photoresist layer 116 of FIG. 1. A trace 402, including activated photoresist may be formed as the combined light is applied to the photoresist layer 116. A width of the trace 402 may not be limited by a wavelength of light used to perform the etching, which represents a substantial advantage over typical photolithography methods. Other advantages may exist.

Multiple types of photoresist may be used with the system 100 described herein, including any photoresist that, when in the presence of a first wavelength of the first light beam 118 and a second wavelength of the second light beam 122, is configured to remain inactive when the first wavelength is greater than the first intensity threshold 206 and the second wavelength is greater than the second intensity threshold 208, and where the photoresist is configured to activate when the first wavelength is less than the first intensity threshold 206 and the second wavelength is greater than the second intensity threshold 208. In some applications, the photoresist may be based on double-stranded DNA oligomers and photochromic moieties intercalated into the double-stranded DNA oligomers.

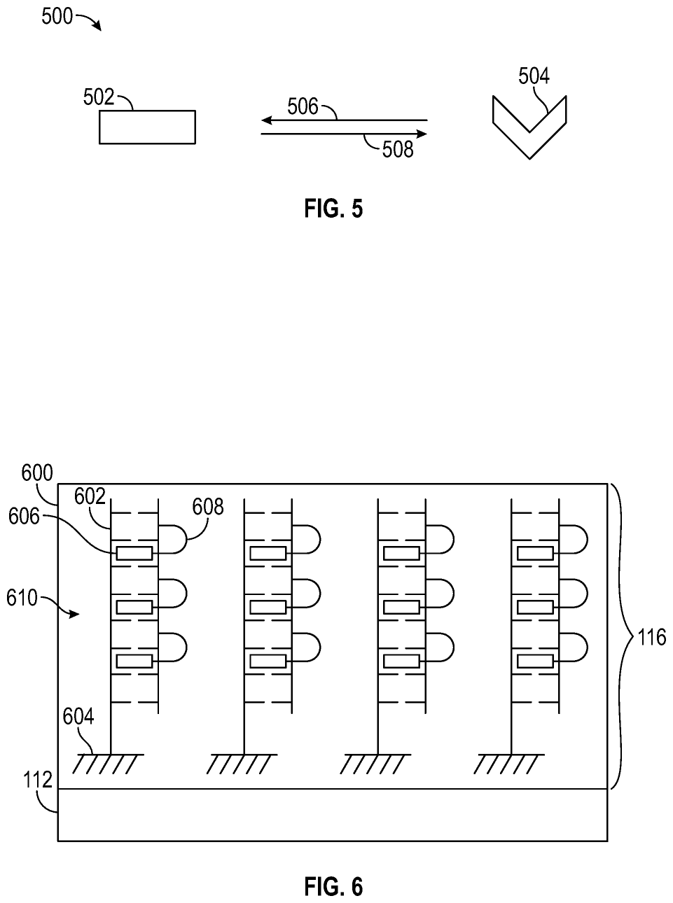

Referring to FIG. 5, an embodiment of a photochromic moiety 500 for use with a DNA-based photoresist is illustrated. The photochromic moiety 500 may adopt a first conformation 502 when a first wavelength 506 is applied. The first wavelength 506 may be associated with the first light beam 118 and the modified first light beam 120 of FIG. 1. The photochromic moiety 500 may adopt a second conformation 504 when a second wavelength 508 is applied. The second wavelength 508 may be associated with the second light beam 122 of FIG. 1. In some applications, the photochromic moieties may be part of a biszaobenzene based compound.

Referring to FIG. 6, an example of a photoresist material 600 is depicted. The photoresist material 600 may form a photoresist layer 116 positioned on a substrate 112. Although not depicted, other layers may also be present as the photoresist material 600 may be used in a multistep microlayer manufacturing process.

The photoresist material 600 may include double-stranded DNA oligomers 602. Although, only one double-stranded DNA oligomer 602 is labeled with a reference number, it should be understood that the photoresist material 600 may include many such oligomers. The double-stranded DNA oligomers 602 may be attached to an inert base 604, as shown, or they may be freely suspended within a bonding material 610. The bonding material may include any kind of suspension that generally holds the photoresist material 600 to the substrate 112.

Photochromic moieties 606 may be intercalated into the double-stranded DNA oligomers 602. A supramolecular interaction 608 may exist between the double-stranded DNA oligomers 602 and the photochromic moieties 606 when the photochromic moieties have the first conformation 502 described with reference to FIG. 5. Although not depicted in FIG. 6, the supramolecular interaction 608 may not exist when the photochromic moieties 606 have the second conformation 504. In FIG. 5 the photochromic moieties 606 each have the first conformation 502.

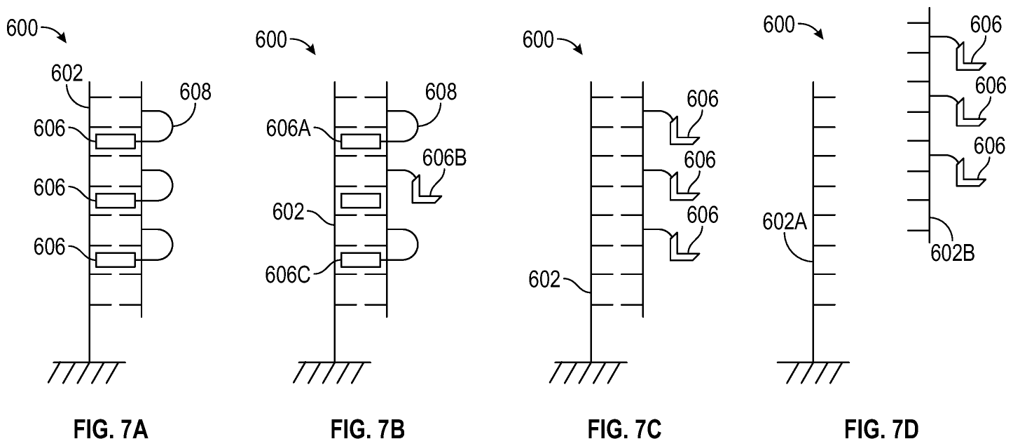

FIGS. 7A-7D depict the photoresist material 600 in various states. For clarity, only one double-stranded DNA oligomer 602 is depicted. Referring to FIG. 7A, the photoresist material may be in the presence of a first wavelength of light such as that of the first light beam 118 and the modified first light beam 120 of FIG. 1. The first wavelength may cause the photochromic moieties 606 to adopt the first conformation 502 depicted in FIG. 5. In the first conformation 502, the photochromic moieties 606 may be drawn into the double-stranded DNA oligomers 602 by the supramolecular interaction 608. While in the double-stranded DNA oligomers 602, the photochromic moieties 606 may lower the system energy and stabilize the double-stranded DNA oligomers 602, preventing them from dissociating.

Referring to FIG. 7B, the photoresist material 600 may be in the presence of both the first wavelength, such as from the first light beam 118 of FIG. 1, and a second wavelength, such as that of the second light beam 122. At any given time, at least some of the photochromic moieties 606A, 606C may have the first conformation 502. Others, such as the photochromic moiety 606B may adopt the second conformation 504, as shown. However, because the photochromic moiety 606B is also in the presence of the first wavelength, it may quickly revert to the first conformation 502. Thus, at any given time, most of the photochromic moieties 606 will have the first conformation and may be retained within the double-stranded DNA oligomer 602 due to the supramolecular interaction 608. This may continue to stabilize the double-stranded DNA oligomer 602.

Referring to FIG. 7C, the photoresist material 600 may be in the presence if the second wavelength while the first wavelength is absent. For example, FIG. 7C may represent the conditions at the center 210 of the combined intensity distribution 200 depicted in FIG. 2. The second wavelength may be selected to cause the photochromic moieties 606 to adopt the second conformation 504. In that case, the supramolecular interaction 608 may cease to exist and the photochromic moieties 606 may be expelled from the double-stranded DNA oligomer 602.

Referring to FIG. 7D, after the photochromic moieties 606 have adopted the second conformation 504 and the supramolecular interaction 608 is removed, the double-stranded DNA oligomer 602 dissociate into a first strand 602A and a second strand 602B. When used as a photoresist material 600, portions of the photoresist material 600 that have dissociated may be considered activated. During processing, either activated portions of the photoresist material may be degraded or inactivated portions may be degraded to provide a photoresist mask for etching processing.

A benefit of the photoresist material 600 is that it can be used along with the photolithography system to perform nanometer resolution photolithography. In particular, the photoresist material 600, when in the presence of light, may remain inactive when a first wavelength of the light is greater than a first intensity threshold and a second wavelength of the light is greater than a second intensity threshold. However, the photoresist material 600 may activate when the first wavelength of the light is less than the first intensity threshold and the second wavelength of light is greater than the second intensity threshold. Other advantages may exist.

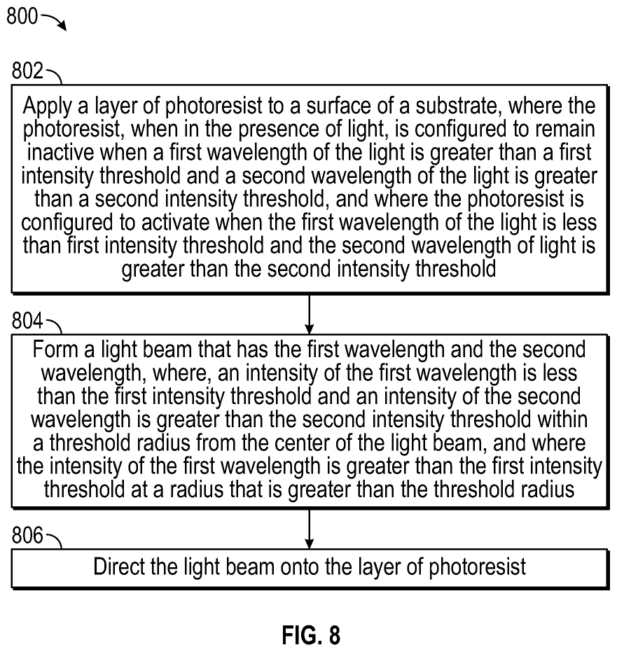

Referring to FIG. 8, a photolithography method 800 is depicted. The method 800 may include applying a layer of photoresist to a surface of a substrate, where the photoresist, when in the presence of light, is configured to remain inactive when a first wavelength of the light is greater than a first intensity threshold and a second wavelength of the light is greater than a second intensity threshold, and where the photoresist is configured to activate when the first wavelength of the light is less than the first intensity threshold and the second wavelength of light is greater than the second intensity threshold, at 802. For example, the photoresist layer 116 may be applied to the surface 114 of the substrate 112. The photoresist layer 116 may include the photoresist 600.

The method 800 may further include forming a light beam that has the first wavelength and the second wavelength, where an intensity of the first wavelength is less than the first intensity threshold and an intensity of the second wavelength is greater than the second intensity threshold within a threshold radius from the center of the light beam, and where the intensity of the first wavelength is greater than the first intensity threshold at a radius that is greater than the threshold radius, at 804. For example, the system 100 may form the combined light beam 124 that has the combined intensity distribution 200.

The method 800 may also include directing the light beam onto the layer of photoresist, at 806. For example, the combined light beam 124 may be directed onto the photoresist layer 116. A benefit of the method 800 is that it can be used to perform nanometer resolution photolithography. Other advantages may exist.

Although various embodiments have been shown and described, the present disclosure is not so limited and will be understood to include all such modifications and variations as would be apparent to one skilled in the art.

What is claimed is:

1. A photoresist material comprising:
double-stranded deoxyribonucleic acid (DNA) oligomers; and
photochromic moieties intercalated into the double-stranded DNA oligomers, wherein a supramolecular interaction exists between the double-stranded DNA oligomers and the photochromic moieties when the photochromic moieties have a first conformation, and wherein the supramolecular interaction does not exist between the double-stranded DNA oligomers and the photochromic moieties when the photochromic moieties have a second conformation.

2. The photo resist material of claim 1, wherein the photochromic moieties, when in the presence of light, adopt the first conformation when a first wavelength of the light is greater than a first intensity threshold and a second wavelength of the light is greater than a second intensity threshold, and wherein the photochromic moieties adopt the second conformation when the first wavelength of the light is less than the first intensity threshold and the second wavelength of the light is greater than the second intensity threshold.

3. The photo resist of claim 1, wherein the photochromic moieties are part of a biszaobenzene based compound.

4. The photo resist material of claim 1, wherein the double-stranded DNA oligomers dissociate in the absence of the supramolecular interaction.

5. The photo resist material of claim 1, further comprising:
a bonding agent configured to adhere the double-stranded DNA oligomers to the surface of a substrate.

6. A photo-lithography method comprising:
applying a layer of photoresist to a surface of a substrate, wherein the photoresist, when in the presence of light, is configured to remain inactive when a first wavelength of the light is greater than a first intensity threshold and a second wavelength of the light is greater than a second intensity threshold, and wherein the photoresist is configured to activate when the first wavelength of the light is less than the first intensity threshold and the second wavelength of the light is greater than the second intensity threshold;
forming a light beam that has the first wavelength and the second wavelength, wherein, an intensity of the first wavelength is less than the first intensity threshold and an intensity of the second wavelength is greater than the second intensity threshold within a threshold radius from the center of the light beam, and wherein the intensity of the first wavelength is greater than the first intensity threshold at a radius that is greater than the threshold radius; and
directing the light beam onto the layer of photoresist.

7. The method of claim 6, wherein forming the light beam comprises:
generating a first light beam having the first wavelength, wherein the first light beam has a first intensity profile that is below the first intensity threshold at a center of the first light beam and that increases as a function of distance from the center of the first light beam and that surpasses the first intensity threshold at the threshold radius from the center of the first light beam;
generating a second light beam having the second wavelength, wherein the second light beam has a second intensity profile with a gaussian distribution that is greater than the second intensity threshold within the threshold radius from the center of the second light beam; and
combining the first light beam and the second light beam.

8. The method of claim 6, wherein generating the first light beam includes passing the first light beam through a phase mask to form the first intensity profile.

9. The method of claim 6, wherein the threshold radius is less than 1 nm.

10. The method of claim 6, wherein the second wavelength is shorter than the first wavelength.

11. The method of claim 6, wherein the first wavelength is in the visible light range and wherein the second wavelength is in the ultraviolet range.

12. The method of claim 6, wherein the photoresist includes:
double-stranded deoxyribonucleic acid (DNA) oligomers; and
photochromic moieties intercalated into the double-stranded DNA oligomers, wherein a supramolecular interaction exists between the double-stranded DNA oligomers and the photochromic moieties when the photochromic moieties have a first conformation, and wherein the supramolecular interaction does not exist between the double-stranded DNA oligomers and the photochromic moieties when the photochromic moieties have a second conformation.

13. The method of claim 12, wherein the photochromic moieties, when in the presence of the light, adopt the first conformation when the first wavelength of the light is greater than the first intensity threshold and the second wavelength of the light is greater than the second intensity threshold, and wherein the photochromic moieties adopt the second conformation when the first wavelength of the light is less than the first intensity threshold and the second wavelength of the light is greater than the second intensity threshold.

14. A photo-lithography system comprising:
a first light source configured to generate a first light beam having a first wavelength;
a phase mask configured to modify the first light beam, wherein an intensity of the first wavelength of the modified first light beam is less than a first intensity threshold within a threshold radius from the center of the modified first light beam, and wherein the intensity of the first wavelength is greater than the first intensity threshold at a radius that is greater than the threshold radius;
a second light source configured to generate a second light beam having a second wavelength, wherein an intensity of the second wavelength of the second light beam is greater than a second intensity threshold within the threshold radius from the center of the second light beam; and
a lens configured to focus the first light beam and the second light beam onto a layer of photoresist applied to a surface of a substrate.

15. The system of claim 14, wherein the photoresist, when in the presence of the first light beam and the second light beam, is configured to remain inactive when the first wavelength is greater than the first intensity threshold and the second wavelength is greater than the second intensity threshold, and wherein the photoresist is configured to activate when the first wavelength is less than the first intensity threshold and the second wavelength is greater than the second intensity threshold.

16. The system of claim 14, wherein the photoresist includes:
double-stranded deoxyribonucleic acid (DNA) oligomers; and
photochromic moieties intercalated into the double-stranded DNA oligomers, wherein a supramolecular interaction exists between the double-stranded DNA oligomers and the photochromic moieties when the photochromic moieties have a first conformation, and wherein the supramolecular interaction does not exist between the double-stranded DNA oligomers and the photochromic moieties when the photochromic moieties have a second conformation.

17. The system of claim 14, further comprising:
a beam combiner configured to combine the first light beam with the second light beam before the first light beam and the second light beam pass through the lens.

18. The system of claim 17, wherein the beam combiner includes a dichroic mirror, a beam splitter, a polarization beam splitter, or a combination thereof.

19. The system of claim 14, wherein the first light source includes a first laser and the second light source includes a second laser.

20. The system of claim 14, wherein the threshold radius is less than 1 nm.
